(19) United States
(12) Patent Application Publication
(10) Pub. No.: US 2025/0219639 A1
(43) Pub. Date: Jul. 3, 2025

(54) SLIDABLE BUTTON ASSEMBLY AND ELECTRONIC DEVICE

(71) Applicant: AAC Acoustic Technologies (Shanghai) Co., Ltd., Shanghai (CN)

(72) Inventor: Chengxiang Shu, Shanghai (CN)

(21) Appl. No.: 18/664,319

(22) Filed: May 15, 2024

Related U.S. Application Data
(63) Continuation of application No. PCT/CN2023/143495, filed on Dec. 29, 2023.

(51) Int. Cl. H03K 17/96; H01H 9/02; H01H 15/00

(52) U.S. Cl. CPC H03K 17/9622; H01H 9/0271; H01H 15/005

(57) ABSTRACT

The present disclosure provides a slidable button assembly and an electronic device. The slidable button assembly includes a support frame, a circuit board secured onto a side of the support frame, a sensor module secured onto a side, away from the support frame, of the circuit board, and a button secured onto a side, away from the circuit board, of the sensor module; wherein the sensor module comprises a plurality of sets of sensor assemblies that are successively arranged and spaced apart from each other, each of the sets of sensor assemblies comprising a plurality of capacitive sensors that are successively arranged and spaced apart from each other, the capacitive sensors being electrically connected to the circuit board. The slidable button assembly according to the present disclosure improves the positioning and sensitivity of progressive adjustment control of the button.

The present application is a continuation of PCT Patent Application No. PCT/CN2023/143495, entitled “SLIDABLE BUTTON ASSEMBLY AND ELECTRONIC DEVICE,” filed Dec. 29, 2023, which is incorporated by reference herein in its entirety.

### TECHNICAL FIELD

The present disclosure relates to the technical field of buttons, and in particular, relates to a slidable button assembly and an electronic device.

### BACKGROUND

Sensors are typically applied to buttons or keys and other components of electronic products, such as mobile phones, watches, and tablet computers, to realize force sensing and positioning functions, which has achieved good user experience.

In the related art, the way of applying sensors to a button or key is to arrange the sensors at two ends of the button or key so as to achieve control by pressing the two ends of the button or key. Although this way improves the user experience, where progressive adjustment control such as lighting dimming, volume control, and graphic equalization is desired, positioning and sensitivity of the control effect thereof may be relatively poor, and an ideal control effect fails to be achieved.

Therefore, it is desired to provide a slidable button assembly to address the above problem.

### SUMMARY

The present disclosure is intended to provide a slidable button assembly and an electronic device to solve the problem in the related art that where a sensor is employed in button control, the positioning and sensitivity of the control are poor.

In a first aspect, some embodiments of the present disclosure provide a slidable button assembly. The slidable button assembly includes a support frame, a circuit board, a sensor module, and a button. The circuit board is secured onto a side of the support frame. The sensor module is secured onto a side of the circuit board, and the side of the circuit board is away from the support frame. The button is secured onto a side of the sensor module, and the side of the sensor module is away from the circuit board. The sensor module comprises a plurality of sets of sensor assemblies that are successively arranged and spaced apart from each other, each of the sets of sensor assemblies including a plurality of capacitive sensors that are successively arranged and spaced apart from each other, the capacitive sensors are electrically connected to the circuit board.

As an improvement, the plurality of sets of sensor assemblies are provided at equal pitches.

As an improvement, the plurality of capacitive sensors are provided at equal pitches.

As an improvement, the support frame includes a bottom plate, two support plates respectively secured onto two ends of the bottom plate, an intermediate plate with two ends being secured onto two respective sides of the two support plates, respectively, the two respective sides of the two support plates are away from the bottom plate, and a top plate arranged on a side of the intermediate plate and spaced apart from the intermediate plate, the side of the intermediate plate is away from the support plate. Two ends of the top plate are secured onto two ends of the intermediate plate via two elastic members, respectively, and the circuit board is secured onto a side of the top plate, the side of the intermediate plate is away from the intermediate plate.

As an improvement, each of the support plates includes a first sub support plate secured onto the bottom plate and a second sub support plate formed by extending from the first sub support plate towards the support plate. End portions of the intermediate plate are secured onto the second sub support plate.

As an improvement, two first mount holes passing through the bottom plate are provided in the bottom plate. A second mount hole is provided at a position corresponding to each of the two first mount holes of each of the two first sub support plates, respectively, and the second mount hole passes through each of the two first sub support plates The two second mount holes are in communication with the two first mount holes, respectively.

As an improvement, the intermediate plate includes a middle plate and two end plates secured onto two ends of the middle plate, respectively. The middle plate is spaced apart from the bottom plate, and the two end plates are secured onto two respective sides of the two sub support plates, respectively, and the two respective sides of the two sub support plates are away from the bottom plate.

As an improvement, the two elastic members are secured onto two respective sides of the two end plates, respectively. The two respective sides of the two end plates are away from the second sub support plate.

As an improvement, each of the two elastic member is made of foam.

In a second aspect, some embodiments of the present disclosure provide an electronic device. The electronic device includes a casing, and a slidable button assembly arranged inside the casing. The slidable button assembly includes a support frame, a circuit board, a sensor module, and a button. The circuit board is secured onto a side of the support frame. The sensor module is secured onto a side of the circuit board, and the side of the circuit board is away from the support frame. The button is secured onto a side of the sensor module, and the side of the sensor module is away from the circuit board. The sensor module comprises a plurality of sets of sensor assemblies that are successively arranged and spaced apart from each other, each of the sets of sensor assemblies including a plurality of capacitive sensors that are successively arranged and spaced apart from each other, the capacitive sensors are electrically connected to the circuit board. A through hole is arranged in a side surface of the casing, and the support frame is secured onto the casing such that a button passes through the through hole and is exposed outside the casing.

As an improvement, the plurality of sets of sensor assemblies are provided at equal pitches.

As an improvement, the plurality of capacitive sensors are provided at equal pitches.

As an improvement, the support frame includes a bottom plate, two support plates respectively secured onto two ends of the bottom plate, an intermediate plate with two ends being secured onto two respective sides of the two support plates, respectively, the two respective sides of the two support plates are away from the bottom plate, and a top plate arranged on a side of the intermediate plate and spaced apart from the intermediate plate, the side of the intermediate plate is away from the support plate. Two ends of the top plate are secured onto two ends of the intermediate plate via two elastic members, respectively, and the circuit board is secured onto a side of the top plate, the side of the intermediate plate is away from the intermediate plate.

As an improvement, each of the support plates includes a first sub support plate secured onto the bottom plate and a second sub support plate formed by extending from the first sub support plate towards the support plate. End portions of the intermediate plate are secured onto the second sub support plate.

As an improvement, two first mount holes passing through the bottom plate are provided in the bottom plate. A second mount hole is provided at a position corresponding to each of the two first mount holes of each of the two first sub support plates, respectively, and the second mount hole passes through each of the two first sub support plates. The two second mount holes being respectively in communication with the two first mount holes.

As an improvement, the intermediate plate includes a middle plate and two end plates secured onto two ends of the middle plate, respectively. The middle plate is spaced apart from the bottom plate, and the two end plates are secured onto two respective sides of the two sub support plates, respectively, and the two respective sides of the two sub support plates are away from the bottom plate.

As an improvement, the two elastic members are secured onto two respective sides of the two end plates, respectively. The two respective sides of the two end plates are away from the second sub support plate.

As an improvement, each of the two elastic member is made of foam.

Compared to the related art, the slidable button assembly according to the present disclosure employs the sensor module in place of the mechanically structured button in the related art, the sensor module is defined to include the plurality of sets of sensor assemblies that are successively arranged and spaced apart from each other, and each of the sets of sensor assemblies is defined to include the plurality of capacitive sensors that are successively arranged and spaced apart from each other. In this way, where progressive adjustment control of the button is desired, actions of a set of sensor assemblies may cause the capacitive sensors in adjacent sensor assemblies to action, and then the resolution of a touch position is caused to be greater than the number of slide sections by central position calculation of an interpolation algorithm, such that the position of pressing with a finger is positioned, slide gestures and degrees are identified by tracking position changes, and hence the sensitivity is enhanced.

### BRIEF DESCRIPTION OF THE DRAWINGS

For clearer descriptions of the technical solutions according to the embodiments of the present disclosure, drawings that are to be referred for description of the embodiments are briefly described hereinafter. Apparently, the drawings described hereinafter merely illustrate some embodiments of the present disclosure. Persons of ordinary skill in the art may also derive other drawings based on the drawings described herein without any creative effort.

FIG. 1 is a schematic three-dimensional structural diagram of a slidable button assembly according to some embodiments of the present disclosure;

FIG. 2 is a schematic exploded structural diagram of a slidable button assembly according to some embodiments of the present disclosure;

FIG. 3 is a sectional view taken along A-A line in FIG. 1;

FIG. 4 is a schematic three-dimensional structural diagram of an electronic device according to some embodiments of the present disclosure; and

FIG. 5 is a sectional view taken along B-B line in FIG. 4.

Reference numerals and denotations thereof: 100—slidable button assembly; 1—support frame; 11—bottom plate; 111—first mount hole; 12—support plate; 121—first sub support plate; 1211—second mount hole; 122—second sub support plate; 13—intermediate plate; 131—middle plate; 132—end plate; 14—top plate; 15—elastic member; 2—circuit board; 3—sensor module; 31—capacitive sensor; 4—button; 41—extension portion; 200—electronic device; 201—casing; 202—through hole.

### DETAILED DESCRIPTION

Unless defined otherwise, all technical and scientific terms used herein have the same meaning as commonly understood by one of ordinary skill in the art to which the present disclosure pertains. The terms used herein in the specification of present disclosure are only intended to illustrate the specific embodiments of the present disclosure, instead of limiting the present disclosure. The terms “comprise,” “include,” and any variations thereof in the specification and claims of the present disclosure and in the description of the drawings are intended to cover a non-exclusive inclusion. Terms such as “first,” “second,” and the like in the specifications, claims or the accompanying drawings of the present disclosure are intended to distinguish different objects, but are not intended to define a specific sequence.

The terms “example” and “embodiment” in this specification signify that the specific characteristic, structures, or features described with reference to the embodiments may be covered in at least one embodiment of the present disclosure. This term, when appearing in various positions of the description, neither indicates the same embodiment, nor indicates an independent or optional embodiment that is exclusive of the other embodiments. A person skilled in the art would implicitly or explicitly understand that the embodiments described in this specification may be incorporated with other embodiments.

It should be noted that the expressions “upper,” “lower,” “left,” “right,” and the like mentioned in the embodiments of the present disclosure are described with reference to the placement states in the drawings, and should not be construed as limiting the embodiments of the present disclosure. Furthermore, it should also be understood that when an element is referred to as being “over” or “under” another element, it is possible that the element directly constitutes “over” or “under” the other element, or that the element constitutes “over” or “under” the other element through intervening elements.

The technical solutions in the embodiments of the present disclosure are described in detail clearly and completely hereinafter with reference to the accompanying drawings for the embodiments of the present disclosure. Apparently, the described embodiments are only a portion of embodiments of the present disclosure, but not all the embodiments of the present disclosure. Based on the embodiments of the present disclosure, all other embodiments derived by persons of ordinary skill in the art without any creative efforts shall fall within the protection scope of the present disclosure.

### First Embodiment

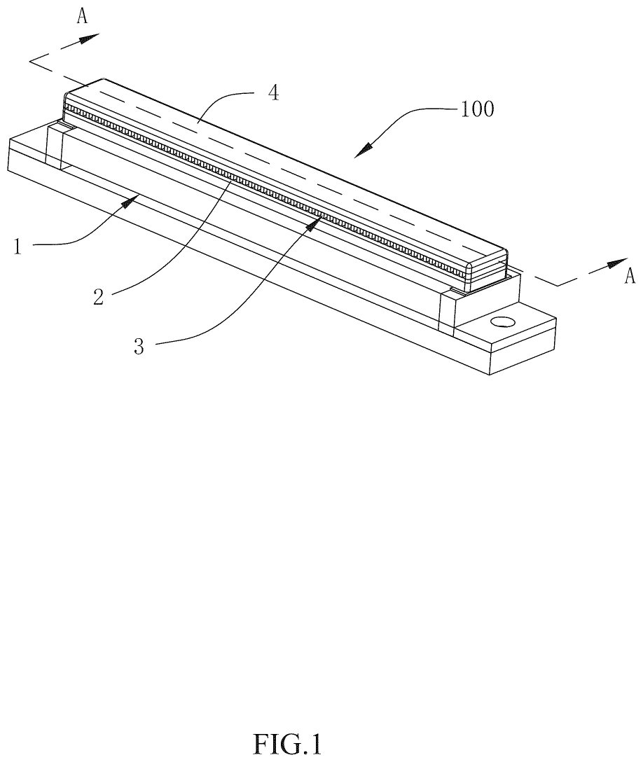

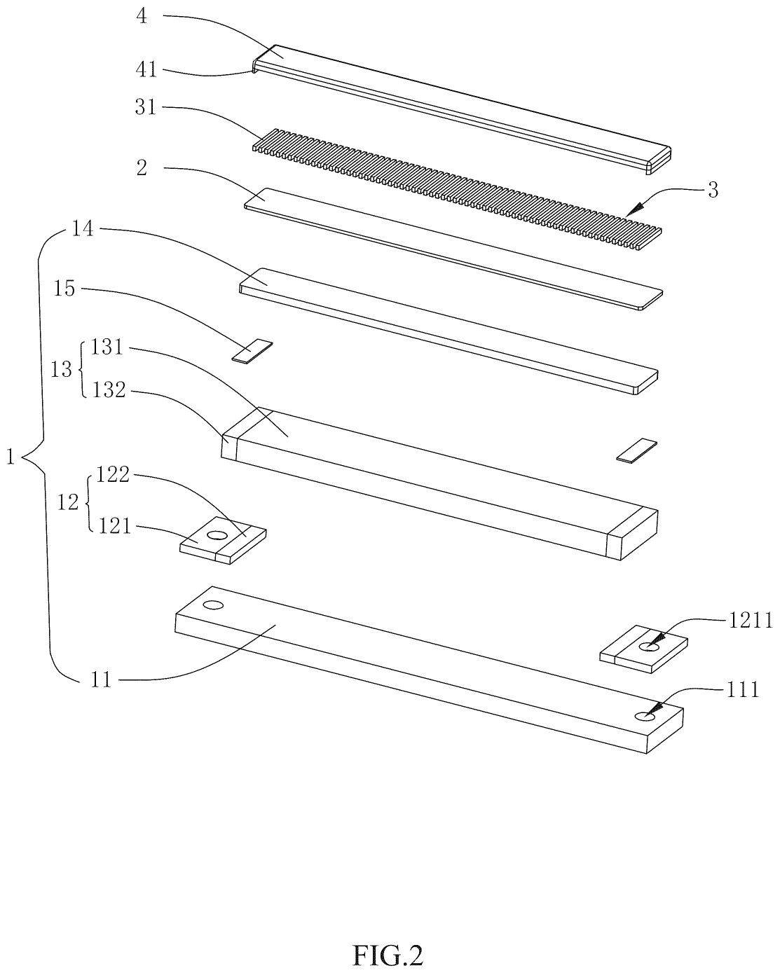

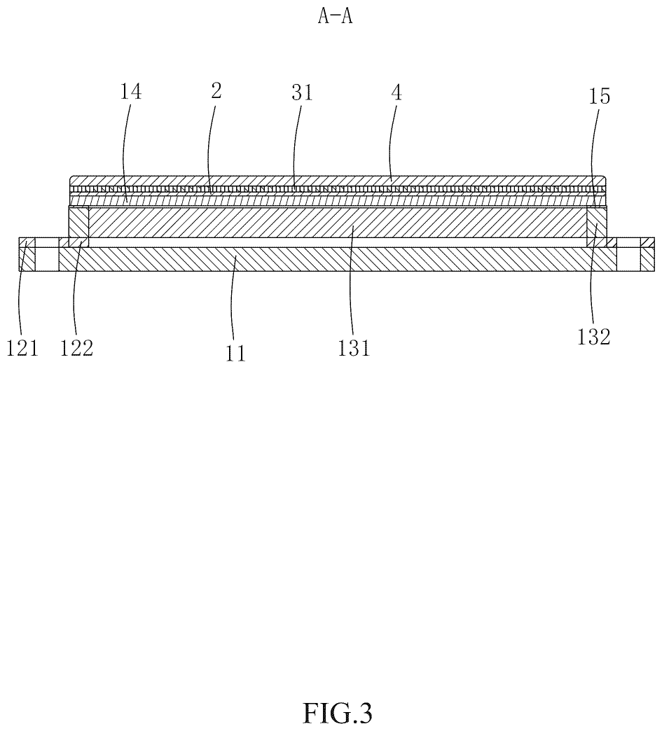

This embodiment provides a slidable button assembly 100. Referring to FIG. 1 to FIG. 3, the slidable button assembly 100 includes a support frame 1, a circuit board 2, a sensor module 3, and a button 4. The circuit board 2 is secured onto a side of the support frame 1. The sensor module 3 is secured onto a side of the circuit board 2, the side of the circuit board 2 is away from the support frame 1. The button 4 is secured onto a side of the sensor module 3, the side of the sensor module 3 is away from the circuit board 2. The sensor module 3 includes a plurality of sets of sensor assemblies that are successively arranged and spaced apart from each other. Each of the sets of sensor assemblies includes a plurality of capacitive sensors 31 that are successively arranged and spaced apart from each other. The capacitive sensors 31 are electrically connected to the circuit board 2.

The number of sensor assemblies and the number of capacitive sensors 31 in each of the sets of sensor assemblies are defined according to actual needs, which are not limited herein. The plurality of capacitive sensors 31 in each of the sets of sensor assemblies may also be referred to as a capacitive sensor segment 31.

In one example, the support frame 1 includes a bottom plate 11, two support plates 12, an intermediate plate 13, and a top plate 14. The two support plates 12 are secured onto two ends of the bottom plate 11, respectively. Two ends of the intermediate plate 13 are secured onto two respective sides of the two support plates 12, respectively, the two respective sides of the two support plates 12 are away from the bottom plate 11. The top plate 14 is provided on a side of the intermediate plate 13 and spaced apart from the intermediate plate 13, the side of the intermediate plate 13 is away from the support plate 12. Two ends of the top plate 14 are secured onto two ends of the intermediate plate 13 via two elastic members 15, respectively. The circuit board 2 is secured onto a side of the top plate 14, the side of the top plate 14 is away from the intermediate plate 13.

Each of the support plates 12 includes a first sub support plate 121 secured onto the bottom plate 11 and a second sub support plate 122 formed by extending from the first sub support plate 121 towards the other support plate 12. An end portion of the intermediate plate 13 is secured onto the second sub support plate 122.

Two first mount holes 111 passing through the bottom plate 11 are provided in the bottom plate 11. A second mount hole 1211 is provided at a position corresponding to each of the two first mount holes 111 of each of the two first sub support plates 121, respectively, and the second mount hole 1211 passes through each of the two first sub support plates 121. In other words, two second mount holes 1211 passing through the two first sub support plates 121 are provided at positions corresponding to the first mount holes 111 of the two first sub support plates 121, respectively. The two second mount holes 1211 are in communication with the two first mount holes 111, respectively. With such a design, the slidable button assembly 100 can be better mounted on the casing of the electronic device through the second mount holes 1211 and the first mount holes 111. Specifically, the second mount hole 1211 passing through each of the two first sub support plates 121 is provided at a position corresponding to each of the two first mount holes 111 of each of the two first sub support plates 121, respectively.

The intermediate plate 13 includes a middle plate 131. And the intermediate plate 13 further includes two end plates 132 secured onto two ends of the intermediate plate 131, respectively. The middle plate 131 is spaced apart from the bottom plate 11. The two end plates 132 are secured onto two respective sides of the two second sub support plates 122, respectively, the two respective sides of the two second sub support plates 122 are away from the bottom plate 11.

Two elastic members 15 are respectively secured onto two respective sides of the two end plates 132, and the two respective sides of the two end plates 132 are away from the second sub support 122.

In one example, the elastic member 15 is made of foam. Nevertheless, the elastic member 15 may be selected from an elastic sheet or an elastic rubber or the like according to actual needs.

In one example, the plurality of sets of sensor modules are provided at equal pitches.

In one example, the plurality of capacitive sensors 31 are arranged at equal pitches. With such a design, the positioning and sensitivity in progressive adjustment control of the slidable button assembly 100 is better improved. Nevertheless, according to actual needs, the plurality of sets of sensor assemblies may also be arranged at unequal pitches, and correspondingly the plurality of capacitive sensors 31 may also be arranged at unequal pitches. Such arrangements, however, have a poor effect compared to the arrangements at equal pitches.

In this embodiment, an extension portion 41 protruding towards the circuit board 2 and abutting against the circuit board 2 is provided at each of two ends of the button 4.

In this embodiment, the slidable button assembly 100 employs the sensor module 3 in place of the mechanically structured button in the related art, the sensor module 3 is defined to include the plurality of sets of sensor assemblies that are successively arranged and spaced apart from each other, and each of the sets of sensor assemblies is defined to include the plurality of capacitive sensors 31 that are successively arranged and spaced apart from each other. In this way, where progressive adjustment control of the button 4 is desired, actions of a set of sensor assemblies may cause the capacitive sensors 31 in adjacent sensor assemblies to action, and then the resolution of a touch position is caused to be greater than the number of slide sections by central position calculation of an interpolation algorithm, such that the position of pressing with a finger is positioned, slide gestures and degrees are identified by tracking position changes, and hence the sensitivity is enhanced.

### Second Embodiment

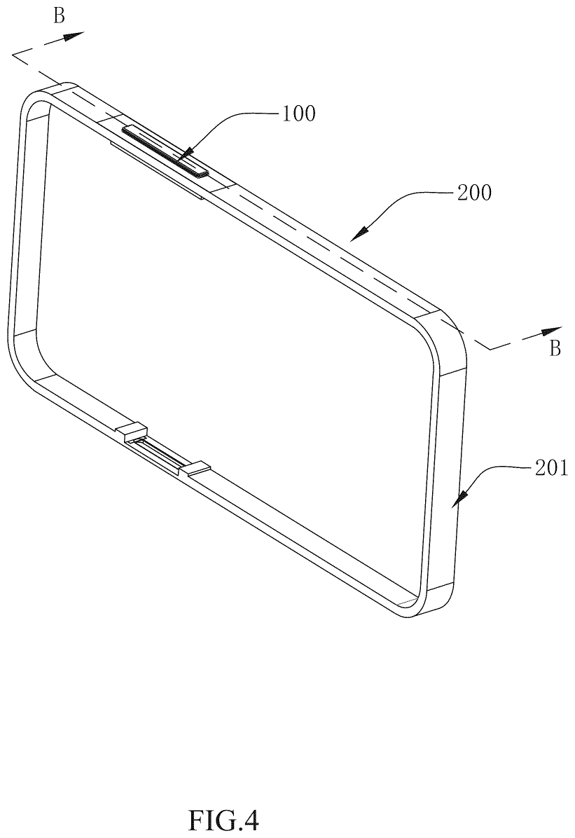

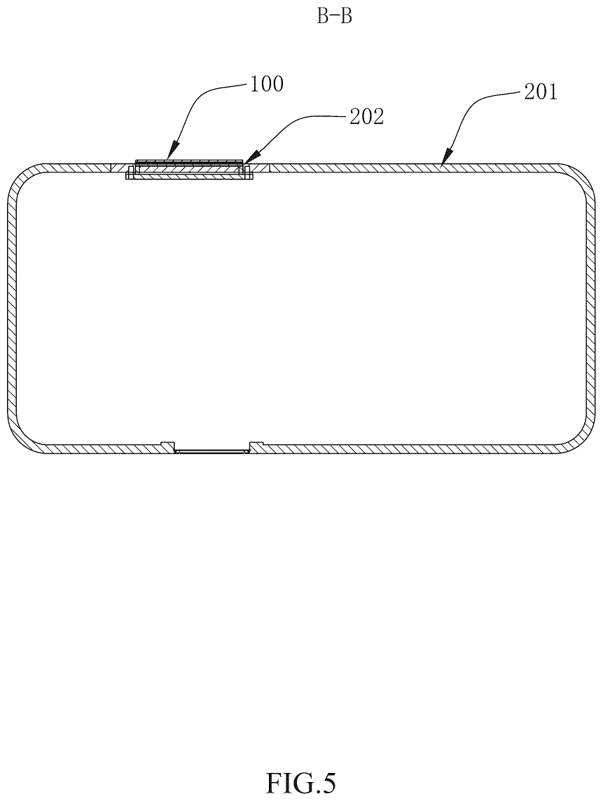

This embodiment provides an electronic device 200. Referring to FIG. 1 to FIG. 5, the electronic device includes a casing 201 and the slidable button assembly 100 according to the first embodiment. A through hole 202 is arranged in a side surface of the casing 201, and a support frame 1 is secured onto the casing 201, such that a bottom 4 passes through the through hole 202 and is exposed outside the casing 201.

The electronic device 200 is a mobile phone, a watch, a tablet computer, or the like.

Since the electronic device 200 according to this embodiment includes the slidable button assembly 100 according to the first embodiment, the electronic device 200 also achieves the technical effects of the slidable button assembly 100 according to the first embodiment, which are not described herein any further.

It should be finally noted that the embodiments described with reference to the accompanying drawings are merely for illustrating rather than limiting the scope of the present disclosure. Persons of ordinary skill in the art shall understand that various modifications or equivalent replacements made to the technical solutions of the present disclosure without departing from the spirit and scope of the present disclosure shall all fall within the scope of the present disclosure. Furthermore, unless the context indicates otherwise, words appearing in the singular form include the plural and vice versa. Additionally, unless specifically stated otherwise, all or a portion of any embodiment may be used in conjunction with all or a portion of any other embodiment.

What is claimed is:

1. A slidable button assembly, comprising:
a support frame;
a circuit board secured onto a side of the support frame;
a sensor module secured onto a side of the circuit board, and the side of the circuit board is away from the support frame; and
a button secured onto a side of the sensor module, the side of the sensor module is away from the circuit board;
wherein the sensor module comprises:
a plurality of sets of sensor assemblies that are successively provided and spaced apart from each other, each of the plurality of sets of sensor assemblies comprises a plurality of capacitive sensors that are successively arranged and spaced apart from each other, and the plurality of capacitive sensors are electrically connected to the circuit board.

2. The slidable button assembly according to claim 1, wherein the plurality of sets of sensor assemblies are provided at equal pitches.

3. The slidable button assembly according to claim 1, wherein the plurality of capacitive sensors are provided at equal pitches.

4. The slidable button assembly according to claim 1, wherein the support frame comprises:
a bottom plate;
two support plates secured onto two ends of the bottom plate, respectively;
an intermediate plate with two ends being secured onto two respective sides of the two support plates, respectively, and the two respective sides of the two support plates are away from the bottom plate;
a top plate arranged on a side of the intermediate plate and spaced apart from the intermediate plate, and the side of the intermediate plate is away from the support plate; and
wherein two ends of the top plate are secured onto two ends of the intermediate plate via two elastic members, respectively; the circuit board is secured onto a side of the top plate, and the side of the top plate is away from the intermediate plate.

5. The slidable button assembly according to claim 4, wherein each of the two support plates comprises:
a first sub support plate secured onto the bottom plate;
a second sub support plate formed by extending from the first sub support plate towards the support plate; and
wherein end portions of the intermediate plate are secured onto the second sub support plate.

6. The slidable button assembly according to claim 5, wherein two first mount holes passing through the bottom plate are provided in the bottom plate; wherein a second mount hole is provided at a position corresponding to each of the two first mount holes of each of the two first sub support plates, respectively, and the second mount hole passes through each of the two first sub support plates; and two second mount holes are in communication with the two first mount holes, respectively.

7. The slidable button assembly according to claim 5, wherein the intermediate plate comprises:
a middle plate;
two end plates secured onto two ends of the middle plate, respectively; and
wherein the middle plate is spaced apart from the bottom plate, and the two end plates are secured onto two respective sides of the two sub support plates, respectively, and the two respective sides of the two sub support plates are away from the bottom plate.

8. The slidable button assembly according to claim 7, wherein the two elastic members are secured onto two respective sides of the two end plates, respectively; the two respective sides of the two end plates are away from the second sub support plate.

9. The slidable button assembly according to claim 4, wherein each of the two elastic member is made of foam.

10. An electronic device, comprising:
a casing;
a slidable button assembly provided inside the casing; the slidable button assembly comprises
a support frame;
a circuit board secured onto a side of the support frame;
a sensor module secured onto a side of the circuit board and the side of the circuit board is away from the support frame; and
a button secured onto a side of the sensor module, the side of the sensor module is away from the circuit board;
wherein the sensor module comprises:
a plurality of sets of sensor assemblies that are successively provided and spaced apart from each other, each of the plurality of sets of sensor assemblies comprises a plurality of capacitive sensors that are successively arranged and spaced apart from each other, and the plurality of capacitive sensors being electrically connected to the circuit board;
wherein a through hole is arranged in a side surface of the casing, and the support frame is secured onto the casing such that the button passes through the through hole and is exposed outside the casing.
